(19) United States
(12) Patent Application Publication
(10) Pub. No.: US 2009/0289301 A1
(43) Pub. Date: Nov. 26, 2009

(54) LASER ANNEALING OF METAL OXIDE SEMICONDUCTORON TEMPERATURE SENSITIVE SUBSTRATE FORMATIONS

(76) Inventors: Chan-Long Shieh, Paradise Valley, AZ (US); Hsing-Chung Lee, Calabasas, CA (US)

Correspondence Address: ROBERT A. PARSONS, 4000 N. CENTRAL AVENUE, SUITE 1220, PHOENIX, AZ, 85012, US

(21) Appl. No.: 12/124,420

(22) Filed: May 21, 2008

(51) Int. Cl. H01L 21/268; H01L 21/28; H01L 27/12

(52) U.S. Cl. 257/347; 438/585; 438/795; 257/E27.112; 257/E21.19; 257/E21.347

(57) ABSTRACT

A method of annealing a metal oxide on a temperature sensitive substrate formation includes the steps of providing a temperature sensitive substrate formation and forming a spacer layer on a surface of the temperature sensitive substrate formation. A metal oxide semiconductor device is formed on the spacer layer, the device includes at least a layer of metal oxide semiconductor material, an interface of the metal oxide layer with a dielectric layer, and a gate metal layer adjacent the layer of metal oxide semiconductor material and the interface. The method then includes the step of at least partially annealing the layer of metal oxide semiconductor material by heating the adjacent gate metal layer with pulses of infra red or visible light radiation.

### FIELD OF THE INVENTION

This invention generally relates to metal oxide semiconductor material in semiconductor devices formed on temperature sensitive substrate formations and more specifically to annealing of the metal oxide semiconductor material for improved reliability and performance.

### BACKGROUND OF THE INVENTION

The figure of merit in thin film transistors (TFTs) is defined by μV/L² where μ is the mobility, V is the voltage and L is the gate length. A major problem is partially remedied by the recent advance in metal oxide semiconductor materials in which mobility as high as 80 cm²/V-sec has been demonstrated. However, the metal oxide semiconductor material presently in use is amorphous, which has mobility and reliability problems. Devices produced at low temperatures in many instances are not stable, exhibiting threshold shift under stress. The stability can be improved by annealing at high temperature.

In the case of the amorphous metal oxide semiconductor material layer, the devices can be produced with more uniformity but the mobility may be less. Performance and stability can be increased by annealing. The mobility of TFTs, for example, and the subthreshold slope can also be improved by annealing. This is due to either or both the mobility of the metal oxide semiconductor or the gate dielectric/metal oxide interface improvement by the high temperature annealing. High temperature annealing reduces traps in the semiconductor/dielectric interface and in the semiconductor material itself, therefore, improving stability. However, high temperature annealing can produce damage in the semiconductor device, i.e. to flexible substrates and/or other plastic layers in the device.

In many applications TFTs are formed on a substrate such as plastic, glass, polymer layers on glass (such as color filters), etc. (hereinafter referred to generically as a temperature sensitive substrate formation) which can only sustain a temperature of approximately 200° C. or less. In such applications it has been proposed that a pulsed ultraviolet (UV) laser provide the required heat. Metal oxide has a very large bandgap and can only absorb energy in the deep UV band. There are two major problems with this type of annealing procedure. One problem is that the temperatures can still be raised because of residual temperature absorption of the substrate, and temperature sensitive substrates, such as flexible or plastic substrates or other plastic layers such as color filters, will melt at this temperature. A second problem is that UV lasers are extremely expensive, causing this annealing method to be very expensive. It would be highly desirable to devise a method of low temperature annealing metal oxide semiconductor material in which the resulting crystals are small enough to improve the mobility as well as the reliability of TFTs formed thereon.

It would be highly advantageous, therefore, to remedy the foregoing and other deficiencies inherent in the prior art.

Accordingly, it is an object of the present invention to provide a new and improved method of annealing a metal oxide semiconductor device on a temperature sensitive substrate.

It is another object of the present invention to provide a new and improved method of annealing metal oxide devices on temperature sensitive substrate formations that is low cost and easy to perform.

It is another object of the present invention to provide a new and improved method of annealing metal oxide devices on temperature sensitive substrate formations that improves the performance and reliability of the semiconductor devices.

### SUMMARY OF THE INVENTION

Briefly, to achieve the desired objects of the instant invention in accordance with a preferred embodiment thereof, provided is a method of annealing a metal oxide on a temperature sensitive substrate formation including the steps of providing a temperature sensitive substrate formation and forming a spacer layer on a surface of the temperature sensitive substrate formation. A metal oxide semiconductor device is formed on the spacer layer, the device includes at least a layer of metal oxide semiconductor material, an interface of the metal oxide layer with a dielectric layer, and a gate metal layer adjacent the layer of metal oxide semiconductor material and the interface. The method then includes the step of at least partially annealing the layer of metal oxide semiconductor material by heating the adjacent gate metal layer with pulses of infra red or visible light radiation.

The desired objects of the instant invention are further achieved in accordance with a preferred embodiment thereof wherein a metal oxide semiconductor device on a temperature sensitive substrate formation includes a temperature sensitive substrate formation, and a spacer layer positioned on a surface of the temperature sensitive substrate formation. The temperature sensitive substrate formation is formed of material that is substantially undamaged by temperatures below approximately 150° C. and the spacer layer includes materials that can withstand temperatures in a range of 300° C. to 800° C. A metal oxide semiconductor device is positioned on the spacer layer, the device including at least a layer of metal oxide semiconductor material, an interface of the metal oxide layer with a dielectric layer, and a gate metal layer adjacent the layer of metal oxide semiconductor material and the interface. The layer of metal oxide semiconductor material and the interface are at least partially annealed.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings in which:

FIG. 1 is a simplified drawing of a top gate thin film transistor on a temperature sensitive substrate formation, in accordance with the present invention;

FIG. 2 is a simplified drawing of a bottom gate thin film transistor on a temperature sensitive substrate formation, in accordance with the present invention; and

FIG. 3 is a simplified diagram illustrating heat dissipation within the spacer layer on a temperature sensitive formation.

### DETAILED DESCRIPTION OF A PREFERRED EMBODIMENT

A major problem in flexible TFT technology stems from the fact that semiconductor material that can be used in TFTs is severely limited by the maximum temperatures to which flexible or plastic containing substrates can be subjected. Layers of metal oxide semiconductor material can be formed at very low temperatures (e.g. room temperature). These metal oxide semiconductors have a relatively high mobility, i.e. compared to other semiconductor materials previously used on flexible substrates. However, the reliability of the low temperature metal oxide is a serious problem. The mobility of the low temperature metal oxide, while relatively good, can be increased by annealing the metal oxide at higher temperatures while substantially increasing the performance and reliability. Annealing of the semiconductor material reduces interface traps (semiconductor/dielectric interface) as well as bulk traps in the semiconductor material. To achieve the best annealing while ensuring that temperature sensitive substrates, such as flexible substrates or substrates containing plastic, are not damaged, it is preferable to limit the substrate temperature to below approximately 150° C. while the metal oxide temperature is raised to over 300° C.

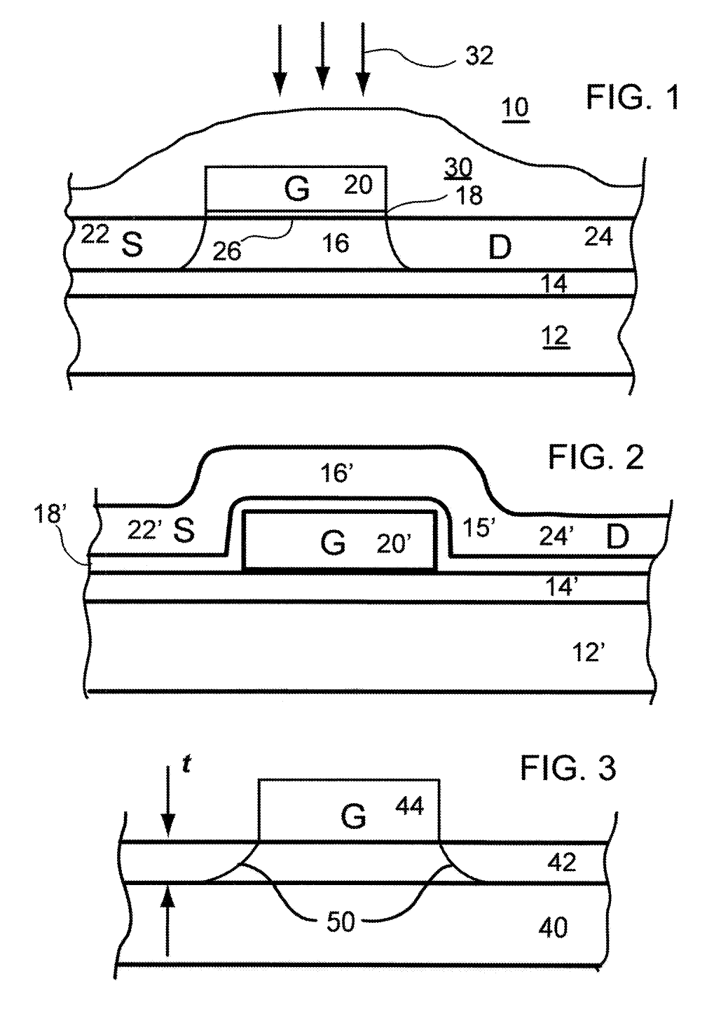

Turning now to FIG. 1, a simplified drawing of a top gate thin film transistor 10 on a temperature sensitive substrate formation 12 is illustrated. Temperature sensitive substrate formation 12 is generally formed to include plastic or other flexible material that has a relatively low melting point. For example, formation 12 may be a flexible substrate, or may be another substrate, such as glass, with one or more layers of plastic or other heat sensitive material thereon. In the method of the present invention a thin spacer layer 14 of low cost material is deposited on the upper surface of temperature sensitive substrate formation 12. Spacer layer 14 is flexible because it is relatively thin, preferably less than approximately 10 microns thick, and is selected from a material that can withstand a higher temperature than formation 12 and which is relatively inexpensive. Examples of materials that are preferable for spacer layer 14 include SiO₂, SiN, polyimide, or BCB. These materials can withstand temperatures in a range of 300° C. to 800° C. without damage. While any of these materials might be too expensive to use in the formation of the entire substrate, the slightly more expensive materials can be economically used to form the relatively thin spacer layer.

The formation of TFT 10 follows a well known procedure generally including at least the following steps. A layer 15 of metal oxide is deposited on spacer layer 14 at temperatures as low as room temperature. In a preferred embodiment metal oxide layer 15 is deposited by a method such as physical vapor deposition or a solution process. A physical vapor deposition process may be, for example, sputtering and solution processes include processes such as spin coating, dip coating, inkjet printing, screen printing, Gravure printing, and the like.

A gate dielectric layer 18 is deposited on the upper surface of metal oxide layer 15 and a gate stack including gate metal 20 is formed on gate dielectric layer 18. Source 22 and drain 24 are formed in layer 15 by some convenient method including, for example, a self-aligned procedure. An active or conductive path or area 16 is defined in layer 15 between source 22 and drain 24 as understood in the art. As an example of this process see the copending United States Patent Application entitled “Self-Aligned Transparent Metal Oxide TFT on Flexible Substrate”, filed Dec. 3, 2007, with application Ser. No. 11/949,477 and included herein by reference. Gate metal 20 includes at least a contact layer of metal that is very close to metal oxide layer 24 and the gate dielectric/metal oxide interface, designated 26. TFT 10 is illustrated with an encapsulation layer 30 covering and encapsulating the device in a well known manner.

To perform an annealing step on metal oxide layer 16, TFT 10 is subjected to short pulses of radiation from an infra red (IR) laser, illustrated as arrows 32. While an infra red laser is preferred, visible light lasers can also be employed. Inexpensive IR semiconductor lasers, generally used for industrial applications, are readily available in the market. While metal oxide layer 16 is transparent to IR radiation, metals such as gate contact metal 20 readily absorb the waves and are heated. In the preferred embodiment, gate metal 20 is irradiated by IR waves 32 which are applied, for example, in less than 50 nanosecond pulses separated by greater than one micro second intervals, sufficiently to achieve the desired temperature.

Using this IR pulsing process, gate metal 20 can be quickly and easily heated to a temperature in a range of 300° C. to 800° C. with the heat being transferred substantially directly to metal oxide layer 16 for annealing thereof. By using short pulses of laser radiation, the energy is absorbed in or near metal oxide semiconductor layer 16 and the spatial and temporal diffusion of the heat creates a big temperature difference between the absorption region and substrate formation 12. Also, spacer layer 14 between the heat absorption region and substrate formation 12 further enhances the temperature difference. Spacer layer 14 is made of inexpensive material that can sustain higher temperatures. Because of the heat diffusion in the spatial and temporal domain, the peak temperature in metal oxide semiconductor layer 16 can be much higher (300° C. to 800° C.) than the temperature of flexible substrate 12 (less than 150° C.).

Here it will be understood by those skilled in the art that the present novel method can also be used on a variety of different semiconductor devices formed on temperature sensitive substrate formations, including for example a typical vertical metal oxide diode structure with the ohmic contact metal serving as a heat absorbing layer. Also, while the above embodiment is performed with encapsulation layer 30 covering and encapsulating TFT 10 it will be understood that it can be performed at anytime subsequent to the formation of the metal contact layer.

Turning now to FIG. 2, a simplified drawing of a bottom gate thin film transistor 10′ on a temperature sensitive substrate formation 12′ is illustrated. Temperature sensitive substrate formation 12′ is generally formed to include plastic or other flexible material that has a relatively low melting point. For example, formation 12′ may be a flexible substrate, or maybe another substrate, such as glass, with one or more layers of plastic material thereon. A specific example of a glass substrate with a plastic layer thereon is a color filter on the substrate, making it a temperature sensitive substrate formation. In the method of the present invention a thin spacer layer 14′ of low cost material is deposited on the upper surface of temperature sensitive substrate formation 12′. Spacer layer 14′ is flexible because it is relatively thin, preferably less than approximately 10 microns thick, and is selected from a material that can withstand a higher temperature than formation 12′ and which is relatively inexpensive. Examples of materials that are preferable for spacer layer 14 include SiO₂, SiN, polyimide, or BCB. These materials can withstand temperatures in a range of 300° C. to 800° C. without damage. While any of these materials might be too expensive to use in the formation of the entire substrate, the slightly more expensive materials can be economically used to form the relatively thin spacer layer.

The formation of TFT 10′ follows a well known procedure generally including at least the following steps. A gate stack including gate metal 20′ is formed on spacer layer 14′ in any of the well known processes. In some instances, in a bottom gate configuration the gate may be planarized to enhance further operations. A gate dielectric layer 18′ is deposited on the upper surface of gate metal 20′ and the planarization surface, if present, or spacer layer 14′, if not present (as illustrated). A layer 16′ of metal oxide is deposited on the upper surface of gate dielectric layer 18′ at temperatures as low as room temperature. Source 22′ and drain 24′ are formed by some convenient method including, for example, a self-aligned procedure (illumination from the bottom if formation 12′ is transparent to the radiation used) in layer 15′. An active or conductive path or area 16′ is defined in layer 15′ between source 22′ and drain 24′, as understood in the art. As an example of this process see the co-pending United States patent application entitled “Self-Aligned Transparent Metal Oxide TFT on Flexible Substrate”, filed Dec. 3, 2007, with application Ser. No. 11/949,477 and included herein by reference.

Referring to FIG. 3, a simplified diagram illustrating heat dissipation within the spacer layer on a temperature sensitive formation is provided. Simply for purposes of this explanation, a temperature sensitive substrate formation 40 is illustrated with a spacer layer 42 formed or deposited thereon. A formation including gate metal 44 is illustrated in a position on the surface of spacer layer 42, as in the bottom gate structure of FIG. 2, but it will be understood that gate metal 44 might be separated from spacer layer 42 by a metal oxide (semiconductor) layer, as in the embodiment illustrated in FIG. 1. In the present annealing process, gate metal 44 is heated by short pulses of infra red radiation. The short pulses of radiation raise the temperature of gate metal 44 sufficiently to heat the adjacent metal oxide to a temperature generally in a range of 300° C. to 800° C. The heat also has a tendency to travel downwardly toward temperature sensitive substrate formation 40. To this end spacer layer 42 is positioned to receive the heat from gate metal 44 and dissipate it outwardly, roughly is indicated by lines 50. The number and duration of pulses of infra red or visible light radiation and the material and thickness ‘t’ of spacer layer 42 are selected such that the temperature at the upper surface of spacer layer 42 may be in the range of 300° C. to 800° C. while the temperature at the junction or interface of spacer layer 42 with temperature sensitive substrate formation 40 is less than 150° C.

In this preferred embodiment (either the structure of FIG. 1 or FIG. 2) it will be understood that the annealing process described converts the metal oxide semiconductor material to reduce traps and the like and, thereby improve reliability and performance and to at least partially improve mobility. Here it will be understood that the annealing step, that is the amount of annealing ultimately performed, will be determined by the specific metal oxide used and the specific formation of the material.

Thus, a new and improved method of annealing a layer of metal oxide semiconductor material in a semiconductor device formed on a flexible substrate has been disclosed. The new and novel method of annealing metal oxide devices on flexible substrates is low cost and easy to perform. The annealing step converts the metal oxide to a structure in which semiconductor devices can be produced with greatly improved performance and reliability. Also, the annealing step converts the metal oxide to a structure with less defects and improved mobility and subthreshold slope. Further, the annealing produces a gate dielectric/metal oxide interface that is improved because traps are eliminated both at the interface and within the semiconductor material.

Various changes and modifications to the embodiment herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of annealing a metal oxide on a temperature sensitive substrate formation comprising the steps of:
providing a temperature sensitive substrate formation;
forming a spacer layer on a surface of the temperature sensitive substrate formation;
forming a metal oxide semiconductor device on the spacer layer, the device including at least a layer of metal oxide semiconductor material, an interface of the metal oxide layer with a dielectric layer, and a gate metal layer adjacent the layer of metal oxide semiconductor material and the interface; and
at least partially annealing the layer of metal oxide semiconductor material by heating the adjacent gate metal layer with pulses of infra red or visible light radiation.

2. A method as claimed in claim 1 wherein the temperature sensitive substrate formation includes plastic.

3. A method as claimed in claim 1 wherein the temperature sensitive substrate formation includes a color filter.

4. A method as claimed in claim 1 wherein the spacer layer is less than 10 microns thick.

5. A method as claimed in claim 1 wherein the spacer layer is formed of material capable of withstanding a higher heat than the temperature sensitive substrate formation.

6. A method as claimed in claim 5 wherein the spacer layer is formed of one of SiO₂, SiN, polyimide, and BCB.

7. A method as claimed in claim 1 wherein the step of forming the spacer layer includes forming the spacer layer with a thickness less than 10 microns.

8. A method as claimed in claim 1 wherein the step of heating includes using an infra red or visible light semiconductor laser and pulsing the laser ON in pulses having a duration of less than 50 nanoseconds.

9. A method as claimed in claim 8 wherein the infra red or visible light semiconductor laser is OFF between On pulses for greater than one micro second.

10. A method as claimed in claim 1 wherein the metal oxide semiconductor device formed includes one of a thin film transistor and a vertical diode.

11. A method as claimed in claim 1 wherein the step of forming the spacer layer includes using a material that is capable of withstanding a temperature in a range of 300° C. to 800° C.

12. A method as claimed in claim 11 wherein the step of heating includes heating the metal contact layer to a temperature in a range of 300° C. to 800° C.

13. A method as claimed in claim 12 wherein the flexible substrate is heated to a temperature less than 150° C.

14. A method as claimed in claim 12 wherein the at least partially annealing step reduces traps in the metal oxide semiconductor material and the interface.

15. A method as claimed in claim 1 wherein the step of forming a metal oxide semiconductor device includes a step of depositing a metal oxide layer by one of physical vapor deposition and a solution process.

16. A method as claimed in claim 15 wherein the step of depositing the metal oxide layer by physical vapor deposition includes sputtering.

17. A method as claimed in claim 15 wherein the step of depositing the metal oxide layer by solution process includes one of spin coating, dip coating, inkjet printing, screen printing, and Gravure printing.

18. A method of annealing a metal oxide on a temperature sensitive substrate formation comprising the steps of:
providing a temperature sensitive substrate formation, the temperature sensitive substrate formation being formed of material that is substantially undamaged by temperatures below approximately 150° C.;
forming a spacer layer on a surface of the temperature sensitive substrate formation, the spacer layer including materials that can withstand temperatures in a range of 300° C. to 800° C.;
forming a metal oxide semiconductor device on the spacer layer, the device including at least a layer of metal oxide semiconductor material, an interface of the metal oxide layer with a dielectric layer, and a gate metal layer adjacent the layer of metal oxide semiconductor material and the interface; and
at least partially annealing the layer of metal oxide semiconductor material by heating the gate metal layer with pulses of infra red or visible light radiation to a temperature in a range of 300° C. to 800° C.

19. A method as claimed in claim 18 wherein the temperature sensitive substrate formation includes plastic.

20. A method as claimed in claim 18 wherein the temperature sensitive substrate formation includes a color filter.

21. A method as claimed in claim 18 wherein the step of forming the spacer layer includes forming the spacer layer with a thickness less than 10 microns.

22. A method as claimed in claim 18 wherein the step of heating includes using an infra red or visible light semiconductor laser and pulsing the laser ON in pulses with a duration of less than 50 nanoseconds.

23. A method as claimed in claim 22 wherein the infra red or visible light semiconductor laser is OFF between On pulses for longer than one micro second.

24. A method as claimed in claim 18 wherein the metal oxide semiconductor device formed includes one of a thin film transistor and a vertical diode.

25. A metal oxide semiconductor device on a temperature sensitive substrate formation comprising:
a temperature sensitive substrate formation, the temperature sensitive substrate formation being formed of material that is substantially undamaged by temperatures below approximately 150° C.;
a spacer layer positioned on a surface of the temperature sensitive substrate formation, the spacer layer including materials that can withstand temperatures in a range of 300° C. to 800° C.; and
a metal oxide semiconductor device positioned on the spacer layer, the device including at least a layer of metal oxide semiconductor material, an interface of the metal oxide layer with a dielectric layer, and a gate metal layer adjacent the layer of metal oxide semiconductor material and the interface, the layer of metal oxide semiconductor material and the interface being at least partially annealed.

26. A metal oxide semiconductor device on a temperature sensitive substrate formation as claimed in claim 25 wherein the metal oxide semiconductor device includes one of a thin film transistor and a vertical diode.

27. A metal oxide semiconductor device on a temperature sensitive substrate formation as claimed in claim 25 wherein the at least partially annealed layer of metal oxide semiconductor material and the interface include substantially reduced traps.
